(19) United States
(12) Patent Application Publication
(10) Pub. No.: US 2017/0059635 A1
(43) Pub. Date: Mar. 2, 2017

(54) CONDUCTIVE TEMPERATURE CONTROL

(71) Applicant: TERADYNE INC., North Reading, MA (US)

(72) Inventors: Shant Orchanian, Winchester, MA (US); Valquirio N. Carvalho, Lowell, MA (US); Philip Campbell, Bedford, NH (US); Matthew David Pollack, Cambridge, MA (US)

(73) Assignee: TERADYNE INC., North Reading, MA (US)

(21) Appl. No.: 14/841,369

(22) Filed: Aug. 31, 2015

(51) Int. Cl. G01R 31/00; G01R 31/28; B25J 18/04; G01R 1/04

(52) U.S. Cl. CPC G01R 31/003; G01R 1/0408; G01R 31/2874; B25J 18/04

(57) ABSTRACT

A test system includes a transporter having test sockets, where each test socket is configured to receive a device to be tested by the test system, and each test socket includes an element that is controllable to change a temperature of a device in the test socket through thermal conduction. The test system includes a test rack comprising slots. The transporter is configured for movement into, and out of, a slot of the test rack to test devices in the test sockets.

### TECHNICAL FIELD

This disclosure relates to controlling temperatures of devices conductively during testing.

### BACKGROUND

During testing, it is common to control the temperature of a device under test (DUT), e.g., to ensure that the DUT remains operational over a specified temperature range. For this reason, the testing environment immediately around the DUT is closely regulated. In some test systems, the temperature within the testing environment is adjusted by using a hot or cold airflow that is common to all of the DUTs in the immediate vicinity.

### SUMMARY

An example test system comprises a transporter having test sockets, with each test socket being configured to receive a device to be tested by the test system, and with each test socket comprising an element that is controllable to change a temperature of a device in the test socket through thermal conduction. A test rack included the test system comprises slots. The transporter is configured for movement into, and out of, a slot of the test rack to test devices in the test sockets. The example test system may include one or more of the following features, either alone or in combination.

The element may be controllable to change the temperature of the device relative to an ambient temperature of the slot. Each test socket may comprise a thermal conductor configured to transfer thermal energy, through conduction, between the element and the device. The thermal conductor may comprise a component that is thermally conductive and that is in thermal contact with the element. The thermal conductor may comprise an interface material that is in contact with the device and that is contactable by the component. The interface material may comprise thermally-conductive tape or thermally-conductive paste.

The test system may comprise a circuit board that mates to the socket, with the component being mounted on the circuit board and being movable relative to the circuit board to contact the interface material. The component may comprise springs to enable movement relative to the device. The component may not be movable relative to the device.

The element may comprise a circuit board that mates to the socket and that increases in temperature in response to an electrical signal. The element may be mounted on the thermal conductor. The element may comprise a passive electrical component that increases in temperature in response to an electrical signal. The element may comprise an active electrical component that increases in temperature in response to an electrical signal. The element may comprise a Peltier device having a part that decreases in temperature in response to an electrical signal.

Each test socket may comprise a thermally-insulating structure surrounding, at least partly, the device, with the thermally-insulating structure inhibiting transfer of thermal energy from the test socket to other test sockets in the transporter. Each test socket comprises a temperature sensor to sense a temperature of at least one of the device or the element. The test system may comprise one or more processing devices to control a temperature of the element based on the temperature sensed by the temperature sensor.

Each element of each test socket may be controllable independently of elements of other test sockets in order to achieve heating or cooling of a device in the test socket concurrently and asynchronously.

Testing performed on devices in the test sockets may comprise functional testing. Testing performed on devices in the test sockets may comprise reliability testing. The reliability testing may comprise burn-in testing.

The test sockets may comprise a first test socket and a second test socket, with a first element in the first test socket being controllable independently of, and asynchronously of, a second element in the second test socket in order to provide independent and asynchronous control over temperatures of devices in the first and second test sockets.

The transporter may comprise a window to receive an air flow to change a temperature of a device in a test socket. The element of the test socket may be controllable based on temperature changes to the device resulting from the air flow.

An example test system may comprise at least one robotic arm operable to rotate through a predetermined arc about, and extend radially from, a first axis substantially normal to a floor; racks arranged around the robotic arm for servicing by the robotic arm; test slots housed by each rack; and transporters that are configured for capture by the at least one robotic arm, and that are configured for movement into, and out of, the test slots, with each transporter having test sockets, with each of the test sockets for holding a device to be tested by the test system when the transporter is in a test slot. For each transporter, a test socket may comprise a thermal circuit to control, through conduction, a temperature of a device held therein independently of control implemented, in others of the test sockets of the transporter, over temperatures of devices held in the others of the test sockets. The example test system may include one or more of the following features, either alone or in combination.

The thermal circuit may comprise an element that is controllable to change in temperature relative to an ambient temperature of a slot containing the transporter. The thermal circuit may comprise a thermal conductor configured to transfer thermal energy, through conduction, between the element and the device. The thermal conductor may comprise a component that is thermally conductive and that is in thermal contact with the element. The thermal conductor may comprise an interface material that is in contact with the device and that is contactable by the component.

The interface material may comprise thermally-conductive tape. The interface material may comprise thermally-conductive paste.

The test system may comprise a circuit board that mates to the socket, with the component being mounted on the circuit board and being movable relative to the circuit board to contact the interface material. The component may comprise springs to enable movement relative to the device. The component may not be movable relative to the device.

The element may be mounted on the thermal conductor. The element may comprise a circuit board that mates to the socket and that increases in temperature in response to an electrical signal. The element may comprise a passive electrical component that increases in temperature in response to an electrical signal. The element may comprise an active electrical component that increases in temperature in response to an electrical signal. The element may comprise a Peltier device having a part that decreases in temperature in response to an electrical signal.

Each test socket may comprise a thermally-insulating structure surrounding, at least partly, the device, with the thermally-insulating structure inhibiting transfer of thermal energy from the test socket to other test sockets in the transporter. Each test socket comprises a temperature sensor to sense a temperature of at least one of the device or the element. The test system may comprise one or more processing devices to control a temperature of the element based on the temperature sensed by the temperature sensor. The test system may comprise a temperature sensor to detect a temperature associated with the test socket; and one or more processing devices to control the element based on the temperature detected.

Any two or more of the features described in this specification, including in this summary section, can be combined to form implementations not specifically described herein.

The test systems and techniques described herein, or portions thereof, can be implemented as/controlled by a computer program product that includes instructions that are stored on one or more non-transitory machine-readable storage media, and that are executable on one or more processing devices to control (e.g., coordinate) the operations described herein. The test systems and techniques described herein, or portions thereof, can be implemented using one or more apparatus, methods, and/or electronic systems that can include one or more processing devices and memory to store executable instructions to implement various operations.

The details of one or more implementations are set forth in the accompanying drawings and the description below. Other features and advantages will be apparent from the description and drawings, and from the claims.

### DESCRIPTION OF THE DRAWINGS

FIG. 1 is a perspective view of an example device test system.

FIG. 2 is a perspective view of an example test slot assembly included in the device test system.

FIGS. 3 and 4 are block diagrams of example self-test and functional test circuitry included in the device test system.

FIG. 5 is a top view of the device test system.

FIG. 6 is a perspective view of the device test system.

FIG. 7 is a perspective view of an example transporter included in the device test system.

FIG. 8 is a perspective view of an example conductive heating assembly included in a socket in the transporter.

FIG. 9 is a cut-away perspective view of the conductive heating assembly.

FIG. 10 is a cut-away perspective view of part of the transporter and a socket containing a cut-away perspective view of the conductive heating assembly.

FIGS. 11 and 12 are perspective shows showing a component of a thermal conductor extended and not extended, respectively.

FIG. 13 is a perspective shows showing a fixed-length component of a thermal conductor.

Like reference symbols in the various drawings indicate like elements.

### DETAILED DESCRIPTION

Described herein are example systems for testing devices, including, but not limited to, semiconductor devices used in solid state storage devices (SSDs). The example systems include transporters that are movable, by a robot, into, and out of, a test slot in a test rack. Each transporter includes multiple test sockets, and each test socket holds a device. In operation, the robot moves a transporter containing devices that have been tested out of a test slot, and moves a transporter containing devices that are to be tested into the test slot. While in the test slot, various types of tests are performed on the devices. Because the devices are in separate test sockets, they may be tested independently, concurrently, and asynchronously. Large numbers of test slots, coupled with multiple sockets per transporter, enables devices to be tested en masse. Use of a robot at least partially automates the testing process as described herein, increasing testing throughput over less automated systems.

Among the tests performed on the devices in the test slots are thermal tests. For example, devices are heated and cooled, and their operational characteristics are determined at resulting reduced and elevated temperatures. Heretofore, heating or cooling in a slot-based test system was implemented by passing hot or cold air through the test slot. However, in a system that includes multiple devices in a single transporter, each of which may be tested differently or be at a different stage in the testing process, convective thermal control alone can be limiting. Accordingly, the example systems described herein use conduction to either heat or cool devices in the test sockets. In an example implementation, each test socket includes an element that is controllable independently of elements of other test sockets in the same transporter in order to heat or cool a device in the test socket through conduction. As a result, the temperature of devices in the same transporter can be controlled independently, concurrently, and asynchronously, thereby enabling thermal testing of different devices in the same transporter to be performed independently concurrently, and asynchronously. So, for example, different types of devices may be loaded into the same transporter, and different thermal tests may be performed on those different types of devices at different times, as described herein.

Devices tested by the system may include any appropriate semiconductor or other testable device. The devices may include, but are not limited to, devices at the integrated circuit (IC) package level, which may be used in various applications, such as solid state drives. A solid-state drive (SSD) is a data storage device that uses solid-state memory to store persistent data. An SSD using SRAM (static random access memory) or DRAM (dynamic random access memory (instead of flash memory) is often called a RAM-drive. The term solid-state distinguishes solid-state electronics from electromechanical devices.

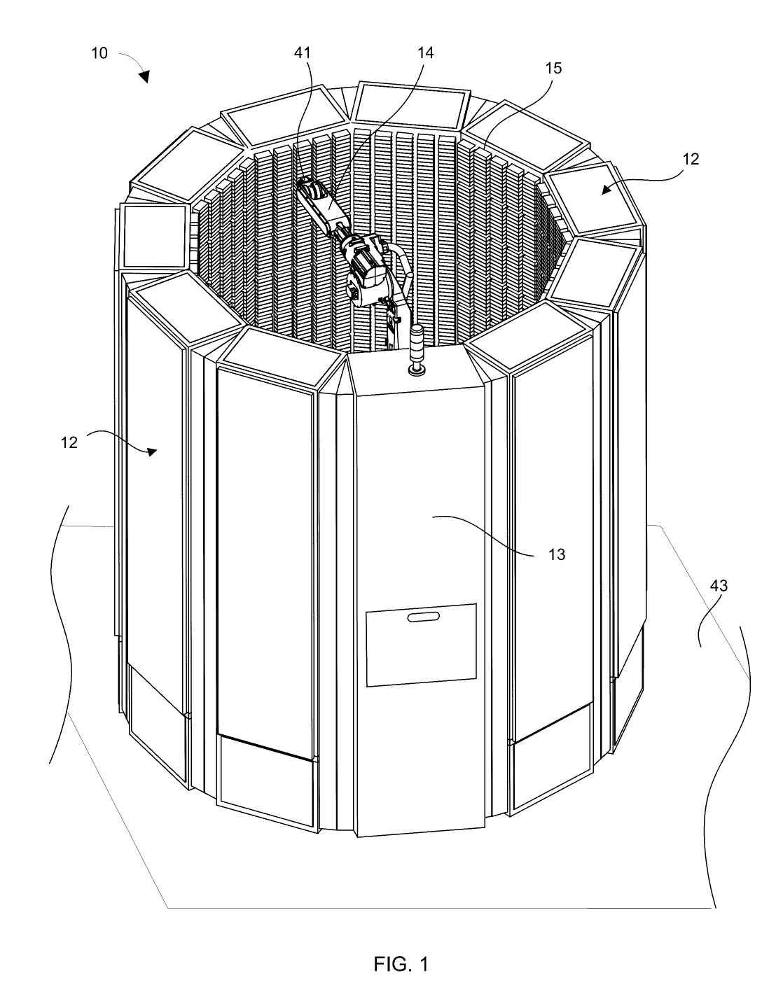

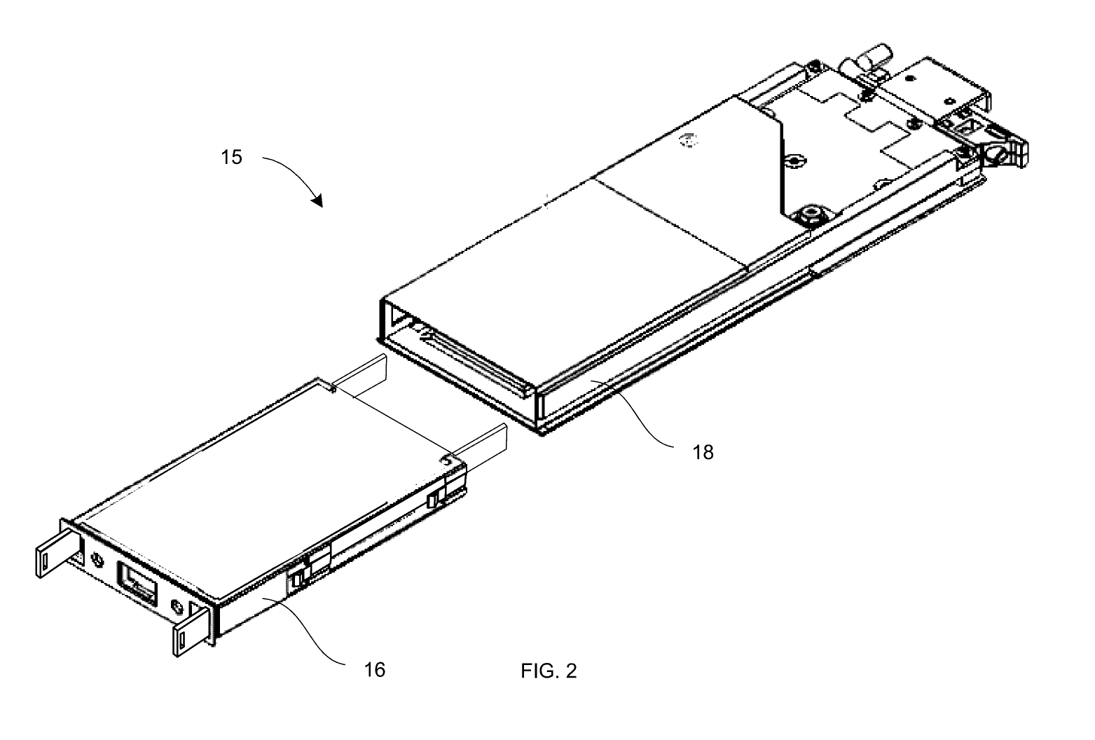

An example implementation of the above-described test system is shown in FIG. 1. As shown in FIG. 1, test system 10 includes a plurality of test racks 12, a loading station 13, and a robot 14. Ten test racks are show in FIG. 1; however, the test system may include any appropriate number of test racks. Each test rack 12 holds a plurality of test slot assemblies 15. As shown in FIG. 2, each test slot assembly 15 includes a device transporter 16 and a test slot 18. The device transporter 16 is configured for holding devices and for transporting the devices to one of the test slots 18 for testing. A device to be tested is also referred to herein as a device under test (DUT). In operation, the transporter remains in the slot during test, and is removed from the slot following device test.

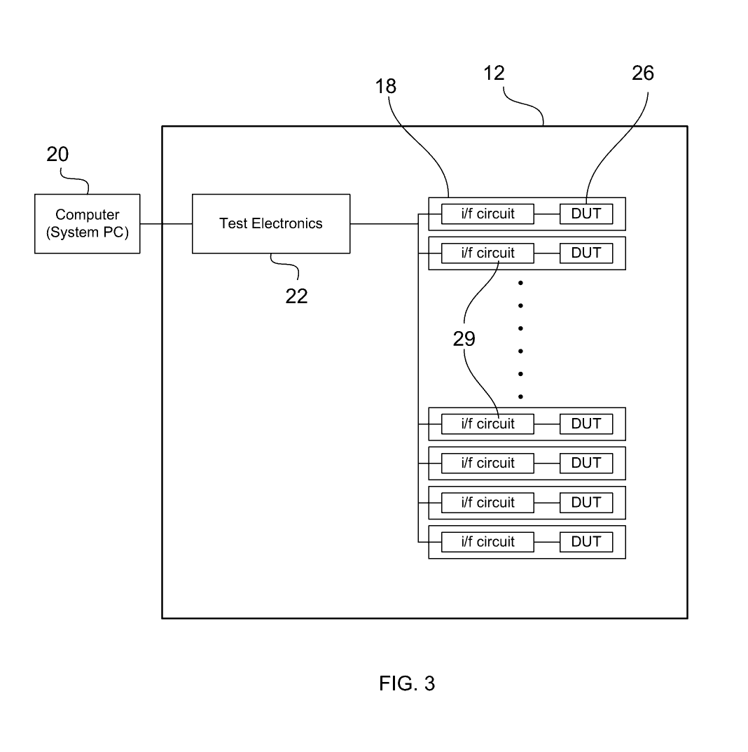

Referring to FIG. 3, in some implementations, the device test system 10 also includes at least one computer 20 (system PC) in communication with the test slots 18. The computer 20 may include one or more processing devices (e.g., multiple computers or devices) and may be configured to provide inventory control of the devices under test and/or an automation interface to control the device test system 10. Within each of the test racks 12, test electronics 22 are in communication with each test slot 18, and may also be in communication with computer 20. The test electronics 22 are configured to communicate with devices received within the test slot 18. The test electronics 22 may include one or more processing devices to execute test processes and monitor the status (e.g., temperature) of the devices under test in the test slot.

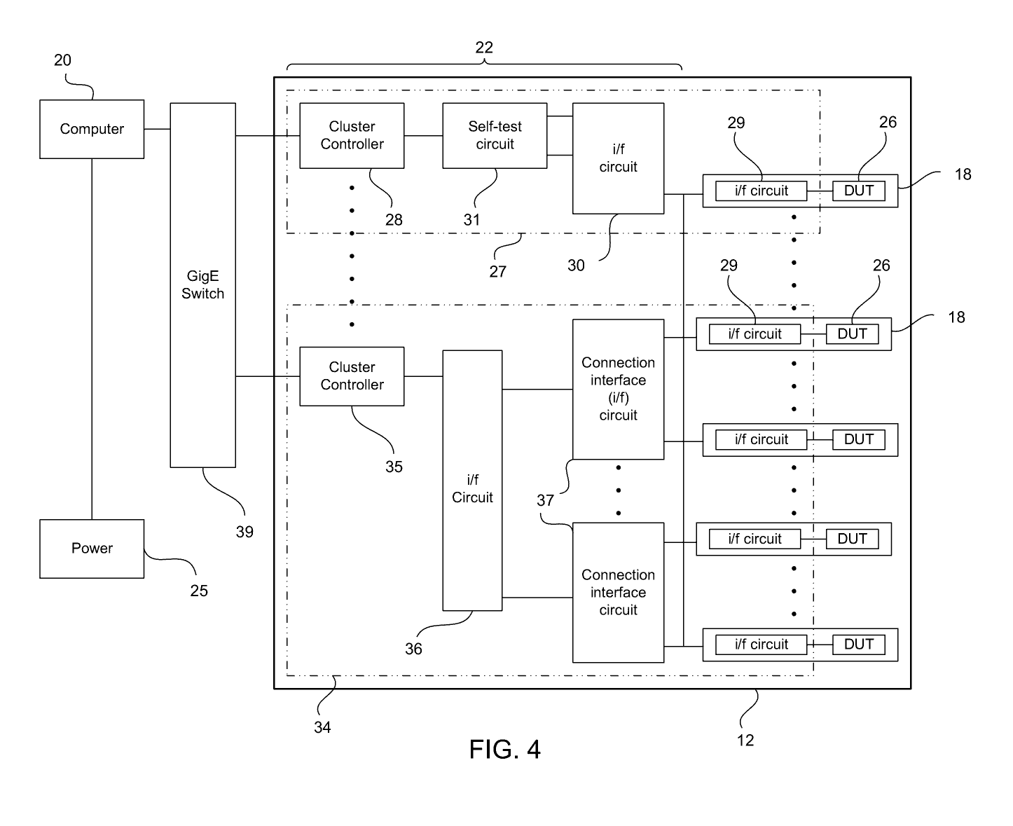

Referring also to FIG. 4, a power system 25 supplies power to the device test system 10. The power system 25 may monitor and/or regulate power to devices 26 in a test slots 18. In the example illustrated in FIG. 4, test electronics 22 within each test rack 12 include at least one self-test system 27 in communication with at least one test slot 18. The self-test system 27 tests whether the test rack 12 and/or specific sub-systems, such as the test slot 18, are functioning properly. The self-test system 27 includes a cluster controller 28, one or more connection interface circuits 29 each in electrical communication with devices received within the test slot 18, and one or more block interface circuits 30 in electrical communication with the connection interface circuit 29. The cluster controller 28, in some examples, is configured to run one or more testing programs. The connection interface circuits 29 and the block interface circuit(s) 30 are configured to self-test. However, the self-test system 27 may include a self-test circuit 31 configured to execute and control a self-testing routine on one or more components of the device test system 10. The cluster controller 28 may communicate with the self-test circuit 31 via Ethernet (e.g. Gigabit Ethernet), which may communicate with the block interface circuit(s) 30 and with the connection interface circuit(s) 29 and DUTs 26 via universal asynchronous receiver/transmitter (UART) serial links. The block interface circuit(s) 30 is/are configured to control power to and temperature of the test slots 18, and each block interface circuit 30 may control one or more test slots 18.

Test electronics 22 can also include test circuitry 34 in communication with at least one test slot 18. The test circuitry 34 tests whether one or more devices held and/or supported in a test slot 18 by a storage device transporter 16, are functioning properly. Test circuitry 34 may control functional testing and reliability (e.g., burn-in) testing. A functionality test may include testing the amount of power received by the device, the operating temperature, the ability to read and write data, and the ability to read and write data at different temperatures (e.g. read while hot and write while cold, or vice versa). A functionality test may test every memory sector of the device or only random samplings. A functionality test may test an operating temperature of the device and also the data integrity of communications with the device. A burn-in test may include reading to, and writing from, each sector of a device, such as a memory, and determining whether the device is reliable based on those operations. Test circuitry 34 may include a cluster controller 35 and at least one interface circuit 36 in electrical communication with a cluster controller 35. A connection interface circuit 37 is in electrical communication with devices received within the test slots 18 and with interface circuit 36. The interface circuit 36 is configured to communicate test routines to the devices in the test slot. The test circuitry 34 may include a communication switch 39 (e.g. Gigabit Ethernet) to provide electrical communication between the cluster controller 28 and the computer. The computer 20, communication switch 39, cluster controllers 28, 35, and the interface circuits may communicate over an Ethernet network or by other appropriate electronic communication media.

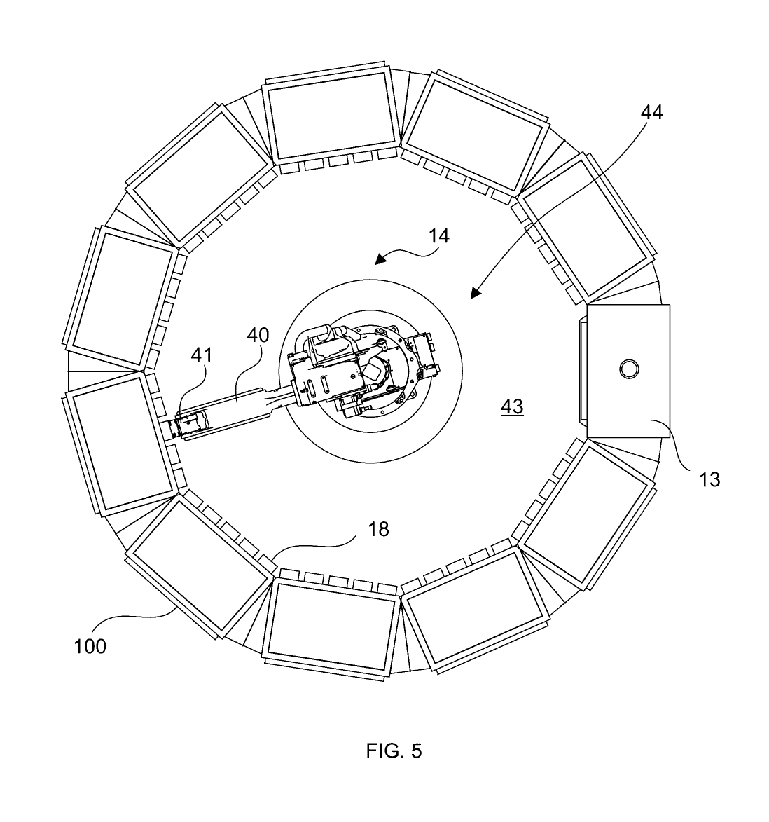

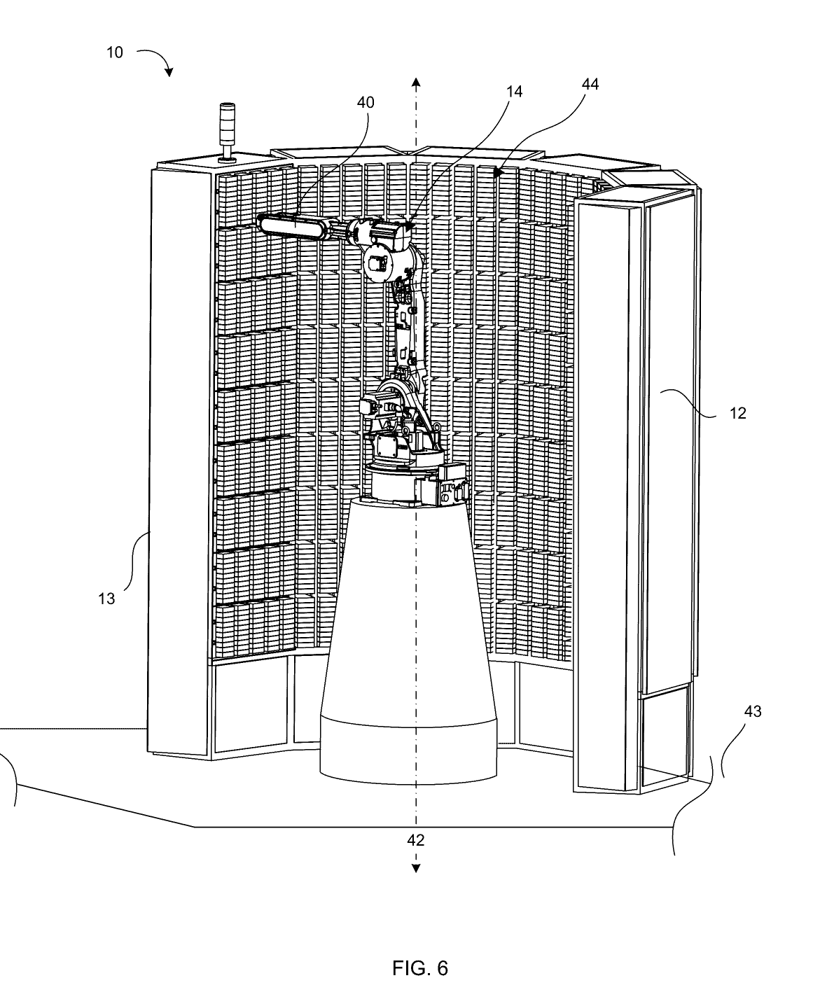

Referring to FIGS. 5 and 6, the robot 14 includes a robotic arm 40 and a manipulator 41 (FIG. 6) disposed at a distal end of the robotic arm 40. The robotic arm 40 defines a first axis 42 (FIG. 6) normal to a floor surface 43 and is operable to rotate through a predetermined arc about and extends radially from the first axis 42 within a robot operating area 44. The robotic arm 40 is configured to independently service each test slot 18. In particular, the robotic arm 40 is configured to move the device transporter 16, with devices to be tested held on sockets contained therein, to the test slot 18 for testing of the devices. After testing, the robotic arm 40 retrieves the device transporter 16, along with the devices that have been tested, from one of the test slots 18 and returns it to a storage device receptacle at a transfer station or loading station 13 or moves it to another one of the test slots 18 by manipulation of the storage device transporter 16 (e.g., with the manipulator 41).

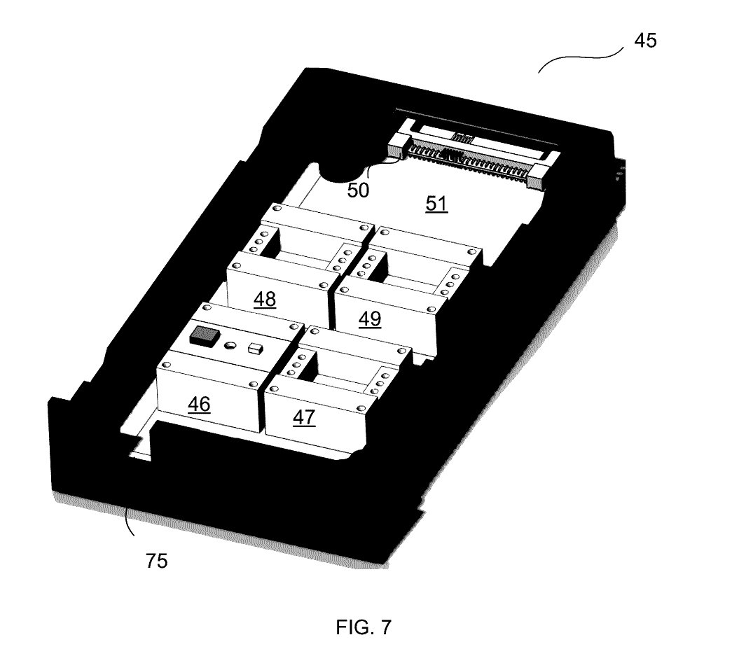

FIG. 7 shows an example of a transporter 45 that is usable as part of test system 10. Transporter 45 includes multiple test sockets 46, 47, 48, 49. In this example four test sockets are shown; however, any appropriate number of test sockets may be used. For example, in some implementations, there may be one, two, three, four, five, six, seven, eight, nine, ten, eleven, twelve, etc. test sockets included in a single slot. Moreover, the arrangement of the test sockets is not limited to that shown in FIG. 7. Rather, the test sockets may be placed in any appropriate arrangement on the transporter.

Each test socket in a transporter is configured to test a device (a DUT) independently concurrently, and asynchronously from other test sockets in that same transporter. For example, in FIG. 7, test socket 46 may test one device independently, and out of synchronism, from another device being tested by socket 47. In some implementations, the devices tested in the same transporter 45 may be the same type of devices (e.g., memory at the IC package level). In some implementations, the devices tested in the same transporter 45 may be different types of devices, which require different types of tests. For example, socket 46 may be used to test one type of device (e.g., a memory) and socket 47 may be used to test a different type of device (e.g., a controller).

Transporter 45 includes an electrical connector 50, which mates to a counterpart connector in a test slot 18. The resulting connection enables transmission, to and from the transporter, of information including, but not limited to, test signals, test results, control signals, and so forth. Any appropriate information that is transmissible over one or more electrical connections may be transmitted to and from the transporter. The information may be transmitted to/from test electronics 22 (or to/from computer 20, as appropriate)

In this example, transporter 45 also includes circuit board 51 containing electrical conduits. The electrical conduits route signals between connector 50 and corresponding test sockets, thus enabling independent and separate communication between individual test sockets and the test electronics (or computer). Among the information communicated are control signals for controlling the temperatures of the test sockets. As described herein, the temperatures of individual test sockets within a single transporter may be controlled independently, concurrently, and asynchronously. For example, at the same time, a device in test socket 46 may be heated, while a device in test socket 47 may be cooled, and a device in test socket 48 may be maintained at the test slot ambient temperature (e.g., no heating or cooling). The independent, concurrent, and asynchronous control over device temperature may be implemented through conductive thermal energy transfer, as described herein.

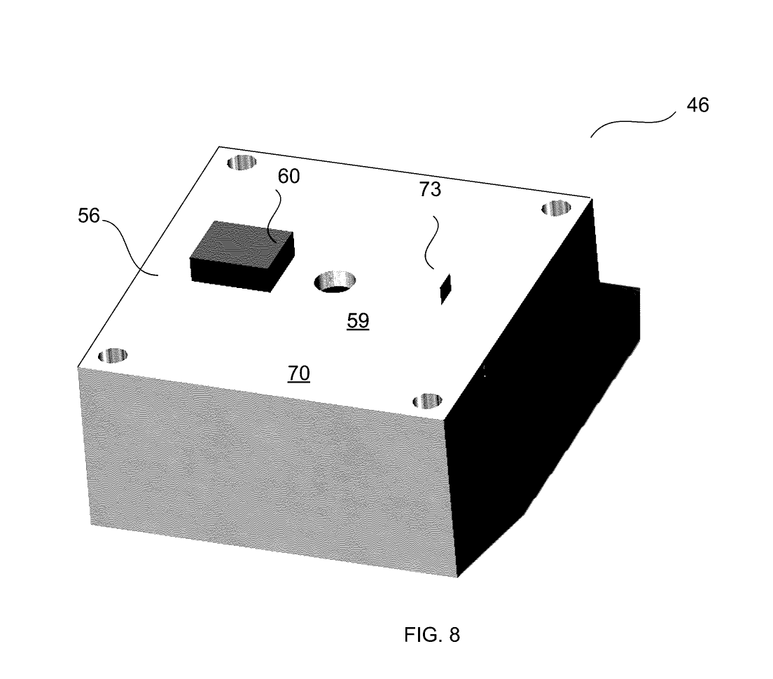

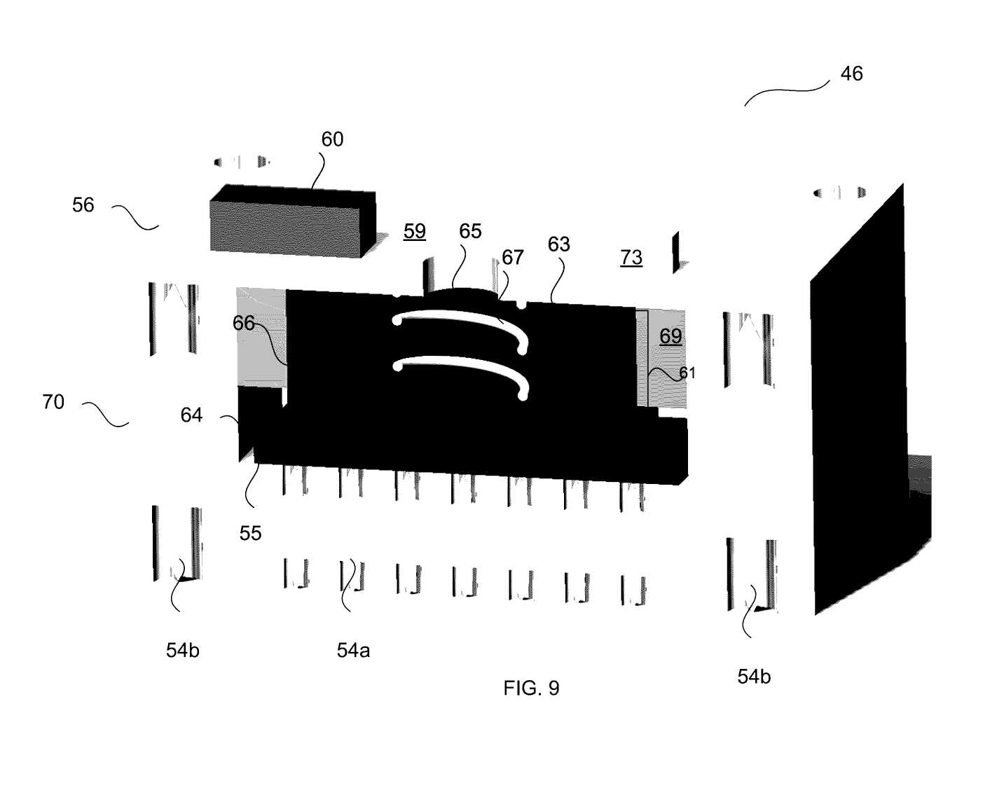

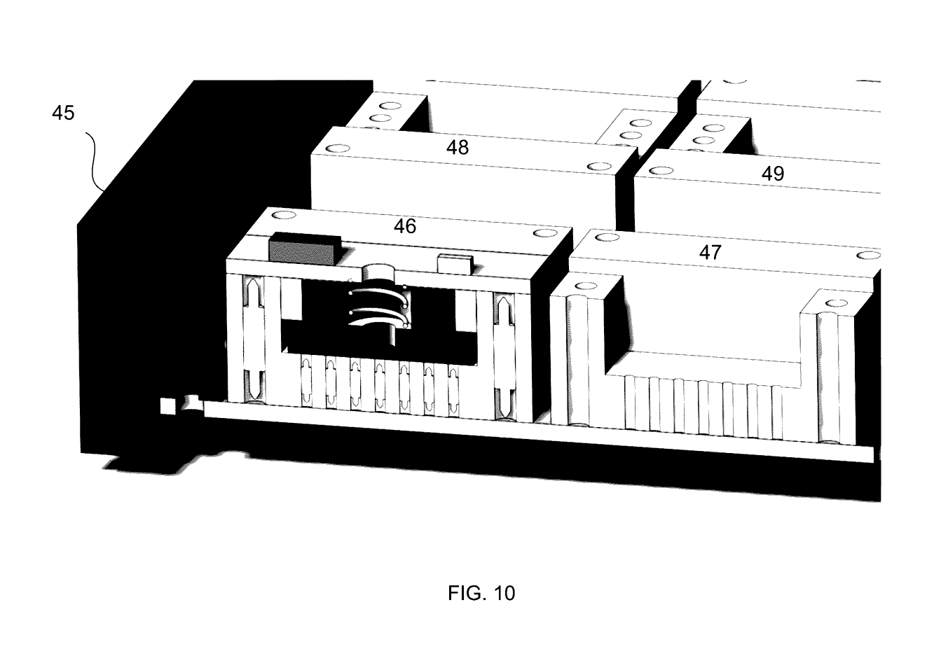

FIG. 8 shows a close-up perspective view of test example test socket 46; FIG. 9 shows a close-up cut-away perspective view of example test socket 46; and FIG. 10 shows a cut-away perspective view of example test socket 46 installed in transporter 45 (only part of which is depicted). The implementation of FIGS. 8 to 10 is an example of how the conductive thermal control is implemented on the test system described herein. Other examples may include different structures or a different arrangement of structures.

Socket 46 includes pins 54a such as POGO® pins, to enable temporary electrical connection to the device in test socket 46, namely DUT 55, absent solder. Test and/or control signals may be sent over this electrical connection between the DUT and the test electronics. DUT 55 may be any type of device that is appropriate for connection to socket 46 and for testing with test system 10. Examples of devices that may be tested are described herein.

Socket 46 also includes assembly 56 for controlling the temperature of DUT 55. In this example, electrical connection to assembly 56 includes pins 54b, such as POGO® pins. Test and/or control signals may be sent over this electrical connection between assembly 56 and the test electronics.

In this example, assembly 56 includes a circuit board 59 to which electrical connection is made. Assembly 56 also includes a thermal control element 60 (or simply, “element 60”). Element 60 is controllable to change the temperature of the device relative to an ambient temperature of a slot in which the device is located, as described herein. Element 60 may be mounted on circuit board 59, as shown, or it may be beneath circuit board 59, internal to circuit board 59, mounted to thermal conductor 61 (described below), or at any other appropriate location internal or external to socket 46. Element 60 includes any appropriate active or passive electrical or thermal device that is controllable (e.g., based on one or more electrical signal(s)) to change a temperature of a device in the test socket through thermal conduction. For example, element 60 may be, or include, a passive device, such as a resistor or a capacitor, that increases in temperature in response to an electrical signal; or an active device, such as a transistor, that increases in temperature in response to an electrical signal. Element 60 may be, or include, traces on circuit board 59 or circuit board 59 itself, either or both of which may heat through conduction of electricity. Element 60 may be, or include, a Peltier device having a part that decreases in temperature in response to an electrical signal. A Peltier device operates to cool the DUT by drawing heat from the DUT. Other types of heating or cooling elements may also be used.

Element 60 and thermal conductor 61 together form a thermal circuit allowing exchange, through conduction, of thermal energy with the DUT. For example, the resulting thermal circuit may conduct heat to the DUT to warm the DUT, or conduct heat away from the DUT to cool the DUT. Thermal conductor 61 (or simply, “conductor 61”) may be a single structure or include multiple structures. In this example, conductor 61 includes a thermally-conductive component 63 (or simply, “component 63”) and a thermally conductive interface material 64 (or simply, “material 64”). In this example, component 63 is made of metal or any other appropriate thermally-conductive material. Component 63 conducts heat between the DUT and element 60. In this example, material 64 is a thermally-conductive tape or paste that is applied directly to the DUT. For example, the conductive tape or paste may be made of graphite or any other appropriate thermally-conductive material. Component 63 comes into contact with interface material 64, thereby completing the thermal circuit that transfers heat between element 60 and the DUT.

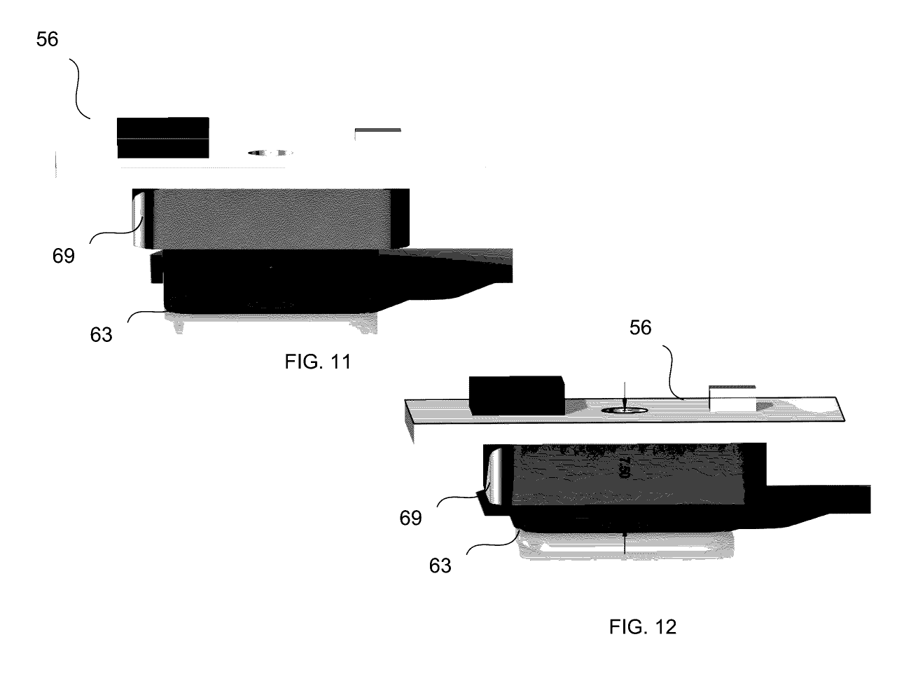

In some implementations, component 63 may be movable relative to circuit board 59 and socket 46. That is, component 63 is mounted on circuit board 59 and is movable in response to contact with the DUT. For example, component 63 may contain one or more springs 67 that enable component 63 to move relative to circuit board in order to compensate for variations in socket depth. Component 63 may be movable within a block 69 that holds the component (e.g., component 63 may act as a piston within block 69). That is, component 63 includes a plunger 65 and a housing 69, which the plunger contacts at a ridge in the housing, with the downward contact forcing the housing downwardly. Block 69 may be made of a thermally-conductive or insulating material. In some implementations, block 69 may not be included in the assembly. FIG. 11 shows an example of assembly 56 with spring 67 extended; and FIG. 12 shows example of assembly 56 with spring 67 compressed, thereby causing component 63 to compress upon contact with the DUT.

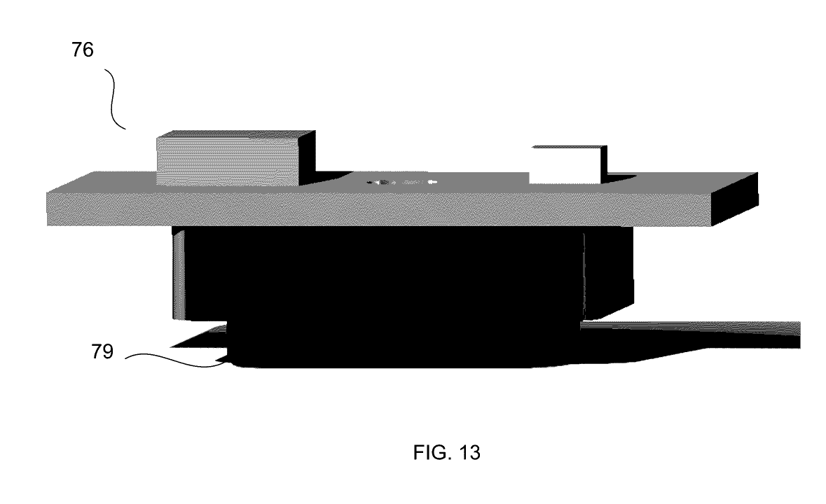

In some implementations, component 63 is not movable relative to circuit board 59 in the socket. For example, component 63 need not include a spring that enables the movement shown in FIGS. 11 and 12. In such implementations, the component may be designed to conform closely to the internal geometry of the socket, or other mechanisms may be provided to compensate for variations in socket depth. For example, the component may be made shorter, and the thermally-conductive paste or other interface material may be made relatively thick to facilitate contact. An example of an assembly 76 in which a component 79 is not movable is shown in FIG. 13.

Referring back to FIGS. 8 to 10, each test socket 46 also includes a thermally insulating structure 70 surrounding, at least partly, DUT 55 and component 63. In some implementations, the thermally-insulating structure may also surround, at least partly, element 60. The thermally-insulating structure forms the body of a test socket, and is includes one or more thermally-insulating materials that inhibit transfer of thermal energy from the test socket to other test sockets in the same transporter. Accordingly, the test sockets may be in close proximity to each other, e.g., within millimeters of each other, with little or no thermal energy being transferred across test sockets. For example, in some implementations, a first test socket may be a following distance from a second test socket with little or no thermal energy being transferred across test sockets by conduction: 1 mm, 2 mm, 3 mm, 4 mm, 5 mm, 6 mm, 7 mm, 8 mm, 9 mm, 10 mm, and so forth. In some implementations, the test sockets may touch.

Any appropriate type of testing may be performed on the devices in the test sockets. For example, functional tests may be performed on devices in the test sockets. Functional tests typically test the operation of devices. Reliability tests may also be performed on devices in the test sockets. Reliability tests, such as burn-in, test whether the device has portions that are faulty or inoperable. Due to the structure and function of the test sockets described herein, different devices in the same transporter/test slot may be subjected to different types of testing. Referring to FIG. 7, a device in socket 46 may be subjected to functional testing while a device in test socket 46 may be subjected to reliability testing.

Referring to FIG. 9, assembly 56 may include a temperature sensor 73 to detect a temperature associated with the test socket. For example, the temperature sensor may be configured to detect the temperature of the DUT itself, the temperature of the socket, and/or the temperature of the element. In the example of FIGS. 8 to 10 (and the other figures), temperature sensor 73 is located on circuit board 59. However, in other implementations, temperature sensor 73 may be below circuit board 59 or elsewhere inside of assembly 56 or test socket 46. Temperature sensor 73 may be connected, through one or more electrical connections in the transporter, to the test computer or test electronics. The test computer or test electronics may monitor the temperature detected by the temperature sensor, and control element 60 accordingly. For example, if the temperature sensor detects that the DUT is below a threshold temperature, signals may be sent to element 60 increase the amount of heat generated by the element. Similarly, if the temperature sensor detects that the DUT is above a threshold temperature, signals may be sent to element 60 to decrease the amount of heat generated by the element or to cool the DUT.

In some implementations, convective heating and/or cooling may also be used in the test system in addition to conductive heating. For example, as shown in FIG. 7, transporter 45 includes a window 75, through which an air flow surrounding the test slot may be drawn over the test sockets. The air flow may contain heated, cooled, or room temperature air. In the implementation of FIG. 7, some air to test sockets 48, 49 may be blocked, at least partly, by test sockets 46, 47. This may result in a temperature differential between test slots 48, 49 and test sockets 46, 47. The conductive temperature control features described herein may be used to compensate for this temperature differential. For example, if the air flow is cool, and test sockets 48, 49 are not sufficiently cooled by the air flow, then the conductive cooling described herein may be used to cool the devices in test sockets 48, 49. In any event, the conductive heating or cooling described herein may supplement or counteract heating or cooling provided by convection in any one or of the sockets.

While this specification describes example transporters related to “testing” and a “test system,” the devices and method described herein may be used in any appropriate system, and are not limited to a testing context or to the example test systems described herein.

Testing performed as described herein may be implemented using hardware or a combination of hardware and software. For example, a test system like the ones described herein may include various controllers and/or processing devices located at various points. A central computer may coordinate operation among the various controllers or processing devices. The central computer, controllers, and processing devices may execute various software routines to effect control and coordination of testing and calibration.

Testing can be controlled, at least in part, using one or more computer program products, e.g., one or more computer program tangibly embodied in one or more information carriers, such as one or more non-transitory machine-readable media, for execution by, or to control the operation of, one or more data processing apparatus, e.g., a programmable processor, a computer, multiple computers, and/or programmable logic components.

A computer program can be written in any form of programming language, including compiled or interpreted languages, and it can be deployed in any form, including as a stand-alone program or as a module, component, subroutine, or other unit suitable for use in a computing environment. A computer program can be deployed to be executed on one computer or on multiple computers at one site or distributed across multiple sites and interconnected by a network.

Actions associated with implementing all or part of the testing and calibration can be performed by one or more programmable processors executing one or more computer programs to perform the functions described herein. All or part of the testing and calibration can be implemented using special purpose logic circuitry, e.g., an FPGA (field programmable gate array) and/or an ASIC (application-specific integrated circuit). Processors suitable for the execution of a computer program include, by way of example, both general and special purpose microprocessors, and any one or more processors of any kind of digital computer. Generally, a processor will receive instructions and data from a read-only storage area or a random access storage area or both. Elements of a computer (including a server) include one or more processors for executing instructions and one or more storage area devices for storing instructions and data. Generally, a computer will also include, or be operatively coupled to receive data from, or transfer data to, or both, one or more machine-readable storage media, such as mass PCBs for storing data, e.g., magnetic, magneto-optical disks, or optical disks. Machine-readable storage media suitable for embodying computer program instructions and data include all forms of non-volatile storage area, including by way of example, semiconductor storage area devices, e.g., EPROM, EEPROM, and flash storage area devices; magnetic disks, e.g., internal hard disks or removable disks; magneto-optical disks; and CD-ROM and DVD-ROM disks.

Any “electrical connection” as used herein may imply a direct physical connection or a connection that includes intervening components but that nevertheless allows electrical signals to flow between connected components. Any “connection” involving electrical circuitry mentioned herein, unless stated otherwise, is an electrical connection and not necessarily a direct physical connection regardless of whether the word “electrical” is used to modify “connection”.

Elements of different implementations described herein may be combined to form other embodiments not specifically set forth above. Elements may be left out of the structures described herein without adversely affecting their operation. Furthermore, various separate elements may be combined into one or more individual elements to perform the functions described herein.

What is claimed is:

1. A test system comprising:
a transporter having test sockets, each test socket being configured to receive a device to be tested by the test system, each test socket comprising an element that is controllable to change a temperature of a device in the test socket through thermal conduction; and
a test rack comprising slots, the transporter being configured for movement into, and out of, a slot of the test rack to test devices in the test sockets.

2. The test system of claim 1, wherein the element is controllable to change the temperature of the device relative to an ambient temperature of the slot; and
wherein each test socket comprises a thermal conductor configured to transfer thermal energy, through conduction, between the element and the device.

3. The test system of claim 2, wherein the thermal conductor comprises:
a component that is thermally conductive and that is in thermal contact with the element.

4. The test system of claim 3, wherein the thermal conductor further comprises:
an interface material that is in contact with the device and that is contactable by the component.

5. The test system of claim 4, wherein the interface material comprises thermally-conductive tape or thermally-conductive paste.

6. The test system of claim 3, further comprising:
a circuit board that mates to the socket, the component being mounted on the circuit board and being movable relative to the circuit board to contact the interface material.

7. The test system of claim 6, wherein the component comprises springs to enable movement relative to the device.

8. The test system of claim 3, wherein the component is not movable relative to the device.

9. The test system of claim 2, wherein the element comprise a circuit board that mates to the socket and that increases in temperature in response to an electrical signal.

10. The test system of claim 2, wherein the element is mounted on the thermal conductor.

11. The test system of claim 2, wherein the element comprises a passive electrical component that increases in temperature in response to an electrical signal.

12. The test system of claim 2, wherein the element comprises an active electrical component that increases in temperature in response to an electrical signal.

13. The test system of claim 2, wherein the element comprises a Peltier device having a part that decreases in temperature in response to an electrical signal.

14. The test system of claim 1, wherein each test socket comprises a thermally-insulating structure surrounding, at least partly, the device, the thermally-insulating structure inhibiting transfer of thermal energy from the test socket to other test sockets in the transporter.

15. The test system of claim 1, wherein each test socket comprises a temperature sensor to sense a temperature of at least one of the device or the element; and
wherein the test system comprises one or more processing devices to control a temperature of the element based on the temperature sensed by the temperature sensor.

16. The test system of claim 1, wherein each element of each test socket is controllable independently of elements of other test sockets in order to achieve heating or cooling of a device in the test socket concurrently and asynchronously.

17. The test system of claim 1, wherein testing performed on devices in the test sockets comprises functional testing.

18. The test system of claim 1, wherein testing performed on devices in the test sockets comprises reliability testing.

19. The test system of claim 18, wherein the reliability testing comprises burn-in testing.

20. The test system of claim 1, wherein the test sockets comprise a first test socket and a second test socket, a first element in the first test socket being controllable independently of, and asynchronously of, a second element in the second test socket in order to provide independent and asynchronous control over temperatures of devices in the first and second test sockets.

21. The test system of claim 1, wherein the transporter comprises a window to receive an air flow to change a temperature of a device in a test socket; and
wherein the element of the test socket is controllable based on temperature changes to the device resulting from the air flow.

22. A test system comprising:
at least one robotic arm operable to rotate through a predetermined arc about, and extend radially from, a first axis substantially normal to a floor;
racks arranged around the robotic arm for servicing by the robotic arm;
test slots housed by each rack; and
transporters that are configured for capture by the at least one robotic arm, and that are configured for movement into, and out of, the test slots, each transporter having test sockets, each of the test sockets for holding a device to be tested by the test system when the transporter is in a test slot;
wherein, for each transporter, a test socket comprises a thermal circuit to control, through conduction, a temperature of a device held therein independently of control implemented, in others of the test sockets of the transporter, over temperatures of devices held in the others of the test sockets.

23. The test system of claim 22, wherein the thermal circuit comprises an element that is controllable to change in temperature relative to an ambient temperature of a slot containing the transporter.

24. The test system of claim 23, wherein the thermal circuit comprises a thermal conductor configured to transfer thermal energy, through conduction, between the element and the device.

25. The test system of claim 23, wherein the thermal conductor comprises:
a component that is thermally conductive and that is in thermal contact with the element.

26. The test system of claim 25, wherein the thermal conductor further comprises:
an interface material that is in contact with the device and that is contactable by the component.

27. The test system of claim 26, wherein the interface material comprises thermally-conductive tape.

28. The test system of claim 26, wherein the interface material further comprises thermally-conductive paste.

29. The test system of claim 25, further comprising:
a circuit board that mates to the socket, the component being mounted on the circuit board and being movable relative to the circuit board to contact the interface material.

30. The test system of claim 29, wherein the component comprises springs to enable movement relative to the device.

31. The test system of claim 25, wherein the component is not movable relative to the device.

32. The test system of claim 24, wherein the element is mounted on the thermal conductor.

33. The test system of claim 23, wherein the element comprise a circuit board that mates to the socket and that increases in temperature in response to an electrical signal.

34. The test system of claim 23, wherein the element comprises a passive electrical component that increases in temperature in response to an electrical signal.

35. The test system of claim 23, wherein the element comprises an active electrical component that increases in temperature in response to an electrical signal.

36. The test system of claim 23 wherein the element comprises a Peltier device having a part that decreases in temperature in response to an electrical signal.

37. The test system of claim 23, wherein each test socket comprises a thermally-insulating structure surrounding, at least partly, the device, the thermally-insulating structure inhibiting transfer of thermal energy from the test socket to other test sockets in the transporter.

38. The test system of claim 24, wherein each test socket comprises a temperature sensor to sense a temperature of at least one of the device or the element; and
wherein the test system comprises one or more processing devices to control a temperature of the element based on the temperature sensed by the temperature sensor.

39. The test system of claim 22, further comprising:
a temperature sensor to detect a temperature associated with the test socket; and
one or more processing devices to control the element based on the temperature detected.

40. The test system of claim 1, further comprising:
a temperature sensor to detect a temperature associated with the test socket; and
one or more processing devices to control the element based on the temperature detected.
